(19) United States
(12) Patent Application Publication
(10) Pub. No.: US 2007/0164457 A1
(43) Pub. Date: Jul. 19, 2007

(54) Semiconductor package, substrate with conductive post, stacked type semiconductor device, manufacturing method of semiconductor package and manufacturing method of stacked type semiconductor device

(75) Inventors: Masahiro Yamaguchi, Tokyo (JP); Hirofumi Nakamura, Tokyo (JP)

Correspondence Address: MCDERMOTT WILL & EMERY LLP, 600 13TH STREET, N.W., WASHINGTON, DC, 20005-3096, US

(73) Assignees: ELPIDA MEMORY INC.; NEC TOPPAN CIRCUIT SOLUTIONS, INC.

(21) Appl. No.: 11/654,670

(22) Filed: Jan. 18, 2007

(30) Foreign Application Priority Data
Jan. 19, 2006 (JP) 2006-011674

(51) Int. Cl. H01L 23/28

(52) U.S. Cl. 257/787

(57) ABSTRACT

A semiconductor package comprising: a substrate containing a wiring pattern connected to a plurality of external electrodes; one or more semiconductor chips connected to the wiring pattern and mounted on the substrate; a conductive post connected to a predetermined the external electrode and functioning as a relay electrode in a vertical direction; and a resin sealing layer for integrally sealing the semiconductor chips and the conductive post in a state in which an upper end face of the conductive post is exposed.

### BACKGROUND OF THE INVENTION

1. Field of the Invention

This invention relates to a stacked type semiconductor memory device formed by stacking a plurality of semiconductor packages, a semiconductor package included in the stacked type semiconductor device, and manufacturing method thereof.

2. Description of the related art

In recent years, attention has been directed toward the POP (Package on Package) technology for stacking a plurality of semiconductor packages to integrally form a stacked type semiconductor device (for example, see JP 2005-45251). The stacked type semiconductor device using the POP technology enables high-density packaging and simplification of manufacturing processes by enabling execution of tests for each semiconductor package individually. When implementing such a stacked type semiconductor device, it is required to form an electrode structure capable of electrically connecting each semiconductor package to the outside. For example, when using a BGA (Ball Grid Array) package, for electrical connection of an upper-layer semiconductor package, a number of solder balls are formed on the lower surface of a substrate of a lower-layer semiconductor package, and part of the solder balls is connected to solder-ball lands separately provided on the substrate via through holes. Then, a structure for connecting to the semiconductor package placed on the upper layer is realized by forming the solder balls on the solder-ball lands. It is thereby possible to form an electrode structure capable of connecting to the upper-layer semiconductor package to be accessed from the outside via the lower-layer semiconductor package.

Generally, in manufacturing a semiconductor package, it is necessary to seal the entire semiconductor package with resin, in a state in which a semiconductor chip is mounted on a semiconductor substrate. However, in the stacked type semiconductor device with the above-mentioned conventional electrode structure, since the upper-layer semiconductor package is joined by solder balls, it is inevitable to adopt a structure in which the resin for sealing is placed apart from the vicinity of the solder-ball lands on the substrate of the lower-layer semiconductor package and narrow regions around the semiconductor chips are sealed with the resin. Therefore, due to a difference in thermal expansion coefficient between regions of the lower-layer semiconductor package according to whether or not the resin is placed, there is a risk that curling and/or distortion of the substrate occurs, which causes a defect in the stacked type semiconductor device.

### BRIEF SUMMARY OF THE INVENTION

It is an object of the present invention to provide a stacked type semiconductor device capable of electrically connecting to an upper semiconductor package without causing curling and/or distortion of a substrate so as to enable high reliability and high-density packaging, when realizing the stacked type semiconductor device having a structure in which a plurality of semiconductor packages is stacked.

An aspect of the present invention is a semiconductor package comprising: a substrate containing a wiring pattern connected to a plurality of external electrodes; one or more semiconductor chips connected to said wiring pattern and mounted on said substrate; a conductive post connected to a predetermined said external electrode and functioning as a relay electrode in a vertical direction; and a resin sealing layer for integrally sealing said semiconductor chips and said conductive post in a state in which an upper end face of said conductive post is exposed.

According to the semiconductor package of the present invention, part of the plurality of external electrodes is connected to the conductive post and functions as the relay electrode reaching the upper end face, so that a structure of electrical connection between the lower and upper layer semiconductor packages is realized. By adopting such a relatively simple structure using the conductive post as the relay electrode, it is possible to seal the conductive post and the semiconductor chip integrally in a wide area on the substrate as compared with, for example, a case in which solder balls for connection are directly disposed on the substrate. Accordingly, it is possible to reliably prevent curling and distortion of the substrate due to the effect of the resin sealing layer, and it is thereby possible to realize the semiconductor package with high reliability and high-density packaging.

In the semiconductor package of the present invention, said conductive post may be made of copper.

In the semiconductor package of the present invention, said plurality of external electrodes and a connection electrode to be connected to the upper end face of said conductive post may be solder balls.

In the semiconductor package of the present invention, the exposed end face of said conductive post may be formed at a position lower than a surface of said resin sealing layer.

In the semiconductor package of the present invention, on a surface of said resin sealing layer, a height of a peripheral area including a position of said conductive post may be lower than a height of a central area.

An aspect of the present invention is a substrate with a conductive post comprising: a substrate containing a wiring pattern connected to a plurality of external electrodes; one or more lands formed on said conductive post and connected to one or more semiconductor chips; and a conductive post connected to a predetermined said external electrode and functioning as a relay electrode in a vertical direction.

In the substrate with a conductive post of the present invention, said conductive post may be made of copper.

An aspect of the present invention is a stacked type semiconductor device which is formed by stacking a plurality of semiconductor packages including said semiconductor package, and enables connection from said predetermined external electrode to a desired semiconductor package through said conductive post.

In the stacked type semiconductor device of the present invention, said plurality of external electrodes and a connection electrode for connecting between adjacent upper and lower semiconductor packages may be solder balls

An aspect of the present invention is a manufacturing method of a semiconductor package comprising the steps of: forming a substrate structure having a wiring pattern and a plurality external electrodes on one side of a conductive plate such that a predetermined said external electrode is connected to a position at which said conductive plate partially functions as a relay electrode; forming a conductive post on the other side of said conductive plate by using a portion at a location functioning as said relay electrode while removing the other portion; mounting one or more semiconductor chips on a surface of said substrate structure at a side on which said conductive plate is removed; sealing said one or more semiconductor chips and said conductive post integrally with a resin; and treating a surface of said resin so that an end face of said conductive post is exposed.

In the manufacturing method of a semiconductor package of the present invention, said conductive post may be made of copper.

In the manufacturing method of a semiconductor package of the present invention, said plurality of external electrodes and a connection electrode to be connected to the upper end face of said conductive post may be solder balls.

The manufacturing method of a semiconductor package of the present invention may further comprise a step of exposing an upper end face of said conductive post at a height slightly lower than a height of a surface of said resin by removing the upper end face of said conductive post.

The manufacturing method of a semiconductor package of the present invention may further comprise a step of forming a peripheral area including a position of said conductive post on a surface of said resin at a height slightly lower than a height of a central area.

An aspect of the present invention is manufacturing method of a stacked type semiconductor device including the above described semiconductor package, in which a connection electrode is connected to the upper exposed end face of said conductive post for connection to one ore more other semiconductor packages in series so as to provide an electrical connection from said predetermined external electrode to a desired semiconductor package through said conductive post.

As described above, according to the invention, since the conductive post is formed as the relay electrode in the vertical direction in the semiconductor package in which the semiconductor chip is mounted on the substrate, it is possible to integrally seal the semiconductor chip and the conductive post with the resin. Accordingly, it is possible to reliably suppress the occurrence of curling and distortion of the substrate, and electrical connection in the vertical direction is enabled in the stacked semiconductor packages without increasing the entire size. Further, by providing a concave structure of the end face of the conductive post and a step structure of the surface of the resin sealing layer, it is possible to stack a plurality of semiconductor packages with sufficiently small gaps therebetween to thin the semiconductor device.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIG. 1 is a diagram showing a cross-sectional structure of a stacked type semiconductor device of a first embodiment;

FIGS. 2A to 2C are diagrams showing steps of manufacturing method of the stacked type semiconductor device of the first embodiment, reaching a step in which an electrolytic plating layer 52 is formed on a copper plate 50;

FIGS. 3A and 3B are diagrams showing steps of the manufacturing method of the stacked type semiconductor device of the first embodiment, reaching a step in which vias 17 are opened after an insulating layer 12 is formed;

FIGS. 4A to 4C are diagrams showing steps of manufacturing method of the stacked type semiconductor device of the first embodiment, reaching a step in which solder-ball lands 14 and a wiring pattern 15 are formed;

FIGS. 5A and 5B are diagrams showing steps of the manufacturing method of the stacked type semiconductor device of the first embodiment, reaching a step in which an etching resist 55 is formed after a solder resist 13 is formed;

FIGS. 6A and 6B are diagrams showing steps of manufacturing method of the stacked type semiconductor device of the first embodiment, reaching a step in which a copper post 18 is formed;

FIGS. 7A and 7B are diagrams showing steps of manufacturing method of the stacked type semiconductor device of the first embodiment, reaching a step in which semiconductor chips 10 and 11 are mounted;

FIGS. 8A and 8B are diagrams showing steps of the manufacturing method of the stacked type semiconductor device of the first embodiment, reaching a step in which solder balls 23 are attached after an end face of the copper post 18 is exposed;

FIG. 9 is a diagram showing a cross-sectional structure of a stacked type semiconductor device of a second embodiment;

FIG. 10 is a diagram showing manufacturing method of the stacked type semiconductor device of the second embodiment;

FIG. 11 is a diagram showing a cross-sectional structure of a stacked type semiconductor device of a modification of the second embodiment;

FIG. 12 is a diagram showing manufacturing method of the stacked type semiconductor device of the modification of the second embodiment.

### DETAILED DESCRIPTION OF THE INVENTION

Embodiments of the present invention will be described below with reference to accompanying drawings. Herein, two embodiments are described each as a stacked type semiconductor device to which the invention is applied.

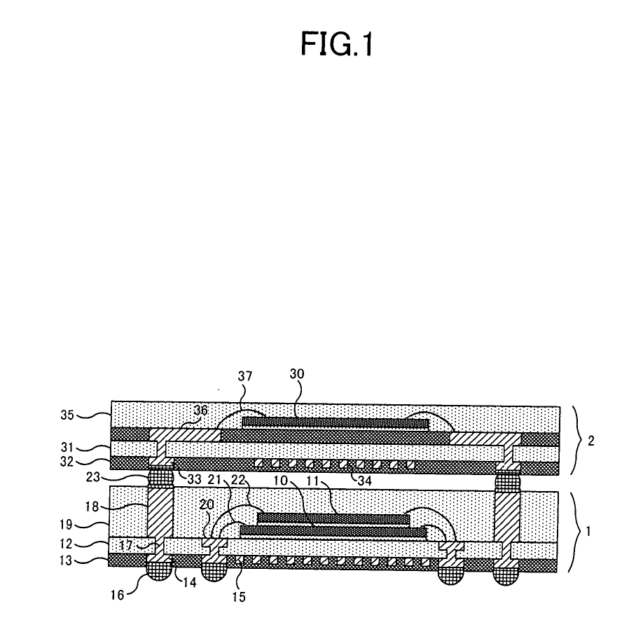

A structure and manufacturing method of a stacked type semiconductor device of a first embodiment will be described first. FIG. 1 shows a cross-sectional structure of the stacked type semiconductor device of the first embodiment. The stacked type semiconductor device of the first embodiment has a first semiconductor package (hereinafter, referred to as a first package) 1 to which the invention is applied, and a second semiconductor package (hereinafter, referred to as a second package) 2 which is electrically connected to the first package 1 and is placed on the first package 1. The first package 1 and the second package 2 are BGA packages and have a structure in which a plurality of electrodes (solder balls) used for electrical connections to the outside and electrical connections between packages are connected with each other in matrix form.

Two semiconductor chips 10 and 11 in which a circuit such as semiconductor memory is formed are disposed and stacked in the first package 1. The lower semiconductor chip 10 is mounted on the center of an insulating layer 12 via an adhesion layer, and the upper semiconductor chip 11 is mounted on the semiconductor chip 10 via an adhesion layer. A wiring layer is formed under the insulating layer 12 and is covered and protected with a solder resist 13. Solder-ball lands 14 and wiring pattern 15 are formed in the wiring layer covered with the solder resist 13. Thus, a substrate structure including the wiring pattern 15 is formed by the insulating layer 12 and the solder resist 13.

A plurality of solder balls 16 is formed under the first package 1, and respectively connected to the solder-ball lands 14. The plurality of solder balls 16 is arranged in two lines on the outer edge side of the first package 1. The outer solder balls 16 are electrically connected to upper copper posts 18 through the solder-ball lands 14 and vias 17 of the insulating layer 12. The copper posts 18 are cylindrical conductive posts formed at positions opposite to the solder balls 16 near the outer edge, and functions as relay electrodes in the vertical direction of the stacked type semiconductor device.

Meanwhile, the solder balls 16 near the center are eclectically connected to bonding lands 20 formed on the upper surface of the insulating layer 12 through the solder-ball lands 14 and vias 17 of the insulating film 12. A bonding wire 21 connected to a pad of the semiconductor chip 10 or a bonding wire 22 connected to a pad of the semiconductor chip 11 is electrically connected to each bonding land 20.

In addition, the semiconductor chips 10 and 11, the bonding wires 21 and 22, and the copper posts 18 are integrally sealed by a resin sealing layer 19 stacked on the insulating layer 12.

In this manner, in the first package 1 of FIG. 1, it is possible to form an electrode structure for connecting from the solder ball 16 to the upper end face of the copper post 18 in the vertical direction. Then, a solder ball 23 as an electrode for connection to the upper-layer second package 2 is connected to the upper end face of the copper post 18. A semiconductor chip 30 is mounted on the second package 2. The solder ball 23 is connected to a solder-ball land 33, a via of an insulating layer 31, a bonding land 36 and a bonding wire 37 in this order, and thus electrically connected to a pad of the semiconductor chip 30. Although the second package 2 has the insulating layer 31, the solder resist 32 and a resin sealing layer 35 as in the first package 1, components corresponding to the copper posts 18 are not provided therein.

A structural feature of the stacked type semiconductor device of the first embodiment is the electrode structure of the first package 1 including the copper post 18. Regarding the lower-layer first package 1, the semiconductor chips 10 and 11 can be electrically connected to the outside through the solder balls 16. In contrast thereto, regarding the upper-layer second package 2, the first package 1 exists between the semiconductor chip 30 and the outside. In other words, the electrode structure is formed, which enables electrical connection from the solder ball 16 to the upper solder ball 23 through the copper posts 18 and thereby a path is formed for electrical connection between the outside and the semiconductor chip 30.

If the copper post 18 is not provided, it is necessary to adopt a structure in which another solder ball is formed on the insulating layer 12 of the first package 1 and the second package 2 is mounted on the solder ball. In this case, it is inevitable to adopt a structure in which the resin sealing layer 19 of the first package 1 is placed apart from the position where the solder balls are disposed for use in connection to the second package 2 and from its surroundings, which causes the occurrence of curling and distortion of the substrate structure. In contrast thereto, in the structure of this embodiment, it is possible to integrally seal the entire region including the semiconductor chips 10, 11 and the copper post 18 by the resin sealing layer 19, so that the first package 1 is maintained without curing and distortion.

It is possible to use a package having a general structure as the second package 2 to which the solder balls 23 can be connected. Although the structure of the first package 1 including two semiconductor chips 10 and 11 is shown in FIG. 1, the number of semiconductor chips mounted on the first package 1 may be appropriately changed, for example, one, three or more, or the like. Similarly, two or more semiconductor chips can be mounted on the second package 2.

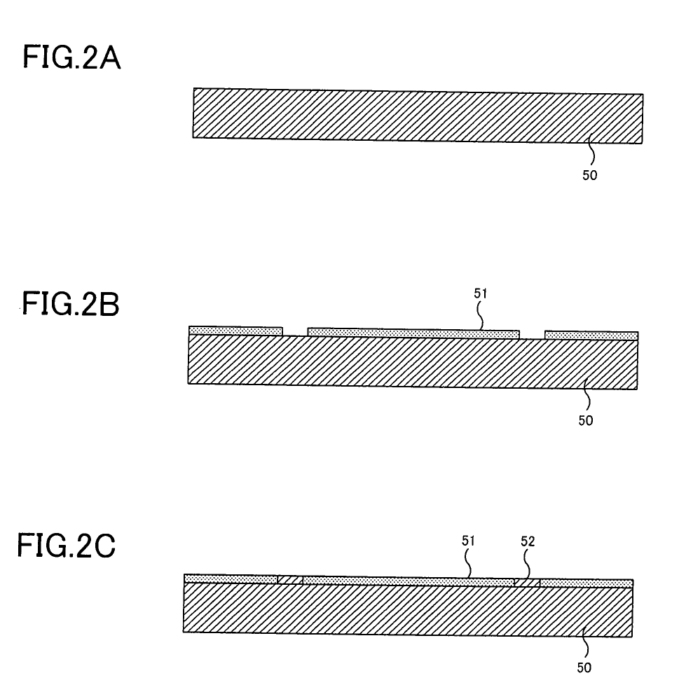

The manufacturing method of the stacked type semiconductor device of the first embodiment will be described next using FIGS. 2 to 8. First, as shown in FIG. 2A, a copper plate 50 having a predetermined thickness (for example, 150 to 200 μm) is prepared to form the copper posts 18. Next, as shown in FIG. 2B, a plating resist 51 is formed on the surface of the copper plate 50. The plating resist 51 is formed by coating or bonding a resist, for example, using photolithography, and by exposing and developing a pattern corresponding to the bonding lands 20 as shown in FIG. 1. Then, as shown in FIG. 2C, an electrolytic plating layer 52 is formed in a region where the plating resist 51 is not formed, for example, using the electrolytic plating method with nickel/gold or nickel/copper.

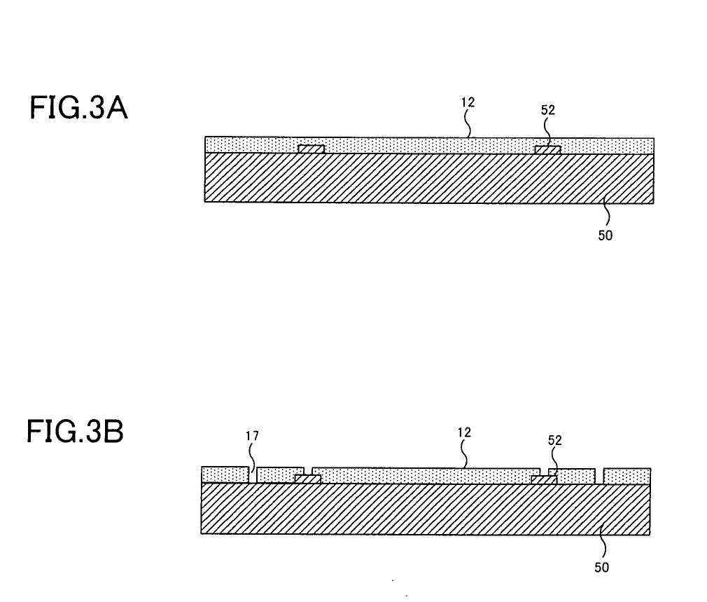

Next, as shown in FIG. 3A, the plating resist 51 is removed from the copper plate 50 on which the electrolytic plating layer 52 is formed, and the insulating layer 12 is formed. The insulating layer 12 is formed, for example, by bonding an epoxy resin material containing glass cloth using laminating press to the upper portion of the copper plate 50 from which the plating resist 51 is removed. Subsequently, as shown in FIG. 3B, a laser beam is applied to the insulating layer 12 at positions opposite to the solder balls 16 to open the vias 17. For example, a carbon dioxide gas laser may be used to open the vias 17.

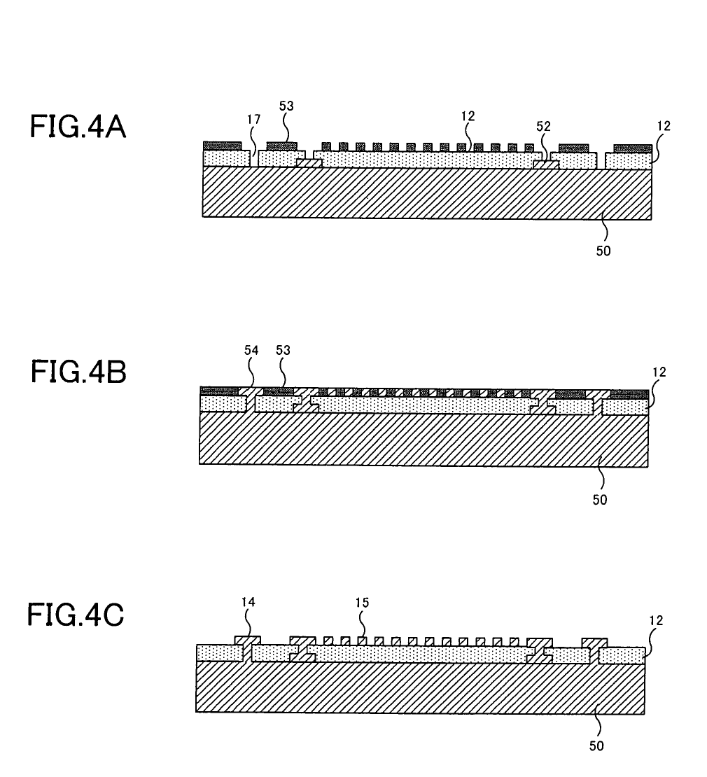

Next, as shown in FIG. 4A, a plating resist 53 is formed on the insulating film 12 having the vias 17. The plating resist 53 is formed, for example, using photolithography similarly as the plating resist 51 of FIG. 2B. At this time, the pattern of the plating resist 53 corresponds to positions of the solder-ball lands 14 and the wiring pattern 15 as shown in FIG. 1. Then, as shown in FIG. 4B, a copper plating layer 54 is formed in a region where the plating resist 53 is not formed using the electrolytic plating method with copper. Subsequently, as shown in FIG. 4C, the plating resist 53 is removed from a predetermined region of the surface of the plating resist 53 and the copper plating layer 54, and thereby the solder-ball lands 14 and the wiring pattern 15 appear.

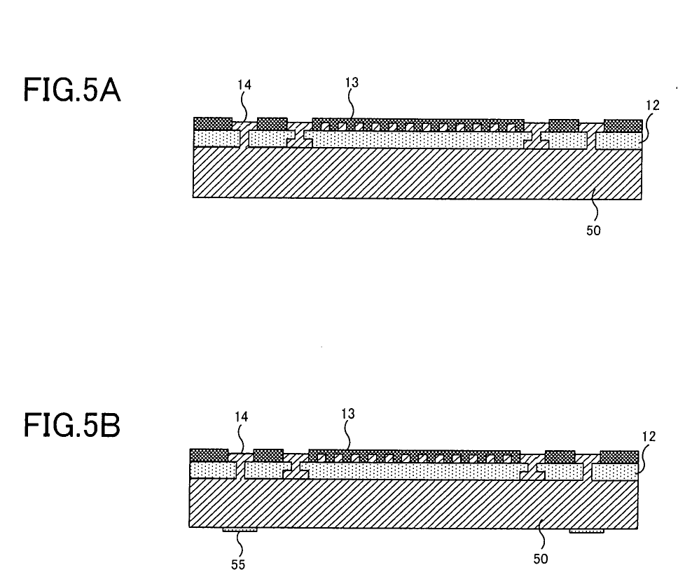

Next, as shown in FIG. 5A, the solder resist 13 for protecting the surface of the wiring pattern 15 is formed, for example, using photolithography. The surface of the solder-ball lands 14 is protected by performing electrolytic gold plating process. Then, as shown in FIG. 5B, an etching resist 55 is formed on the back surface (surface opposite to the insulating layer 12) of the copper plate 50, which has a pattern corresponding to the positions of the copper posts 18 of FIG. 1. In this case, after a plating resist is formed on the back surface of the copper plate 50, for example, using photolithography, a nickel layer may be formed as the etching resist 55.

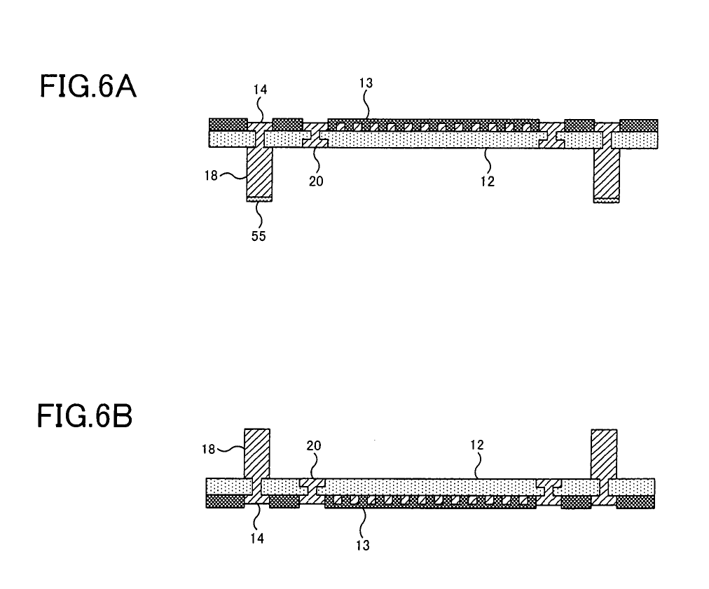

Next, as shown in FIG. 6A, etching is performed on the back surface of the copper plate 50 on which the etching resist 55 is formed, and the cylindrical copper posts 18 are formed. The region at which the etching resist 55 is not formed in the copper plate 50 are removed to the depth reaching the insulating layer 12, for example, by alkali etching, and the remaining regions become the copper posts 18. At this time, the bonding lands 20 masked by nickel appear on the back surface of the insulating layer 12. Then, as shown in FIG. 6B, the etching resist 55 is removed from the end faces of the copper posts 18. In drawings from FIG. 6b, the top and bottom are inverted compared to drawings to FIG. 6A.

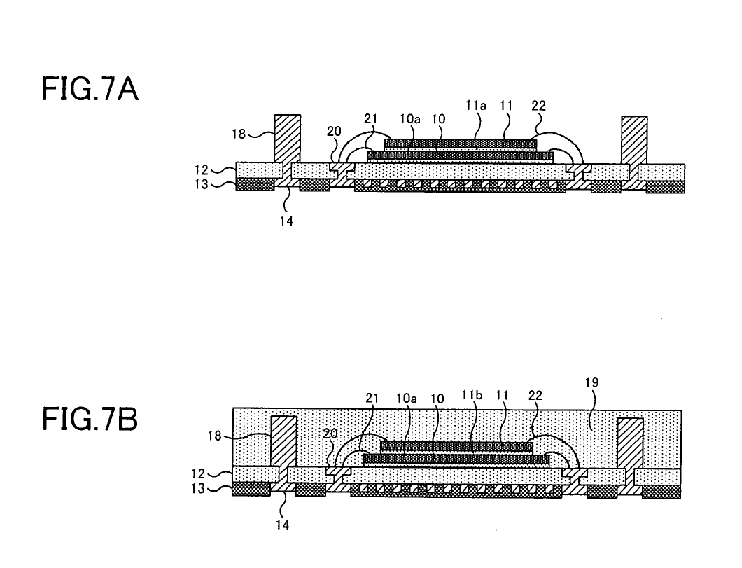

Next, as shown in FIG. 7A, the semiconductor chip 10 is mounted on the center of the insulating layer 12, and then the semiconductor chip 11 is mounted on the semiconductor chip 10. An adhesive is used to fix the insulating layer 12 and the semiconductor chips 10 and 11 respectively. Further, the bonding wires 21 and 22 are respectively connected between the semiconductor chips 10, 11 and the bonding lands 20. Thereafter, as shown in FIG. 7B, the entire region including the semiconductor chips 10 and 11, the copper posts 18 and the like is integrally sealed by being covered with the resin sealing layer 19.

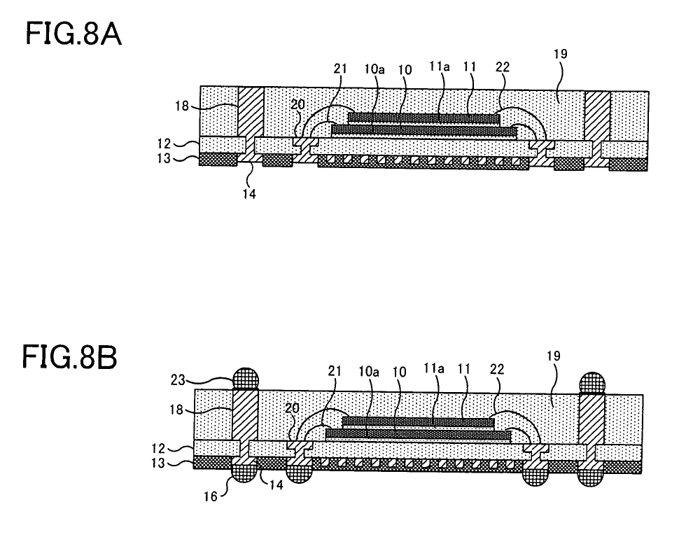

Next, as shown in FIG. 8A, the sealing resin layer 19 of FIG. 7B is ground so as to expose the end faces of the copper posts 18. Then, as shown in FIG. 8B, the solder balls 16 as the external electrodes are placed on the solder-ball lands 14 and are attached thereto. After the surface treatment is performed on the exposed end faces of the copper posts 18, the solder balls 23 as the connection electrodes are disposed and attached thereto. Subsequently, the upper portions of the solder balls 23 are attached to the lands of the second package 2 assembled beforehand so that the second package 2 is mounted on the first package 1, and thereby the stacked type semiconductor device having the structure as shown in FIG. 1 is completed.

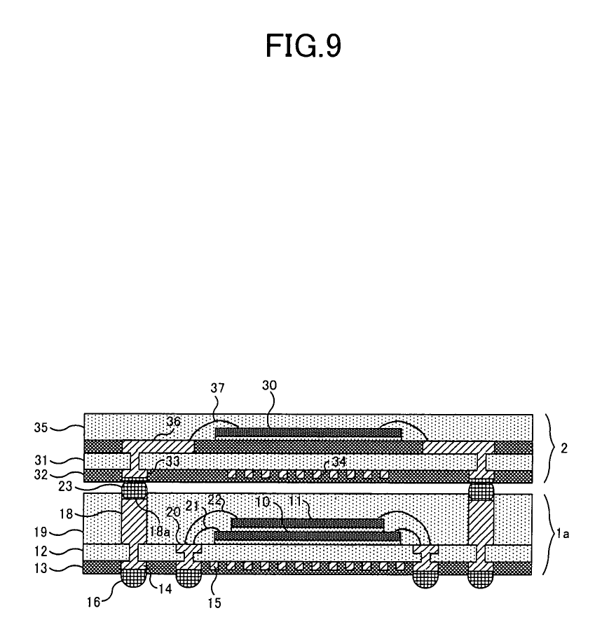

Next, a structure and manufacturing method of a stacked type semiconductor device of a second embodiment will be described. FIG. 9 shows a cross-sectional structure of the stacked type semiconductor device of the second embodiment. The stacked type semiconductor device of the second embodiment has a first package 1a and a second package 2. The basic structure of the second embodiment is similar to that of the first embodiment, but the upper structure of the first package 1a is different from that of the first embodiment. In FIG. 9, components denoted by the same reference numerals as in FIG. 1 has the same structures as those in the first embodiment, so descriptions thereof will be omitted.

The stacked type semiconductor device of the second embodiment features that the upper face of the first package 1a is not flat and the end faces 18a of the copper posts 18 are formed at a lower position. That is, as shown in FIG. 9, the upper portion of each copper post 18 is removed at the upper face of the first package 1a, and the exposed end faces 18a are slightly lower than the surface of the resin sealing layer 19. The solder balls 23 are disposed on the end faces 18a of the copper posts 18, and the second package 2 is mounted on the solder balls 23.

When the structure as shown in FIG. 9 is adopted, each solder ball 23 is disposed in a state in which the lower portion thereof is inserted into the concave portion of the end face 18a of the copper post 18. In this case, the resin sealing layer 19 acts as a solder dam on each solder ball 23 around which the resin sealing layer 19 is placed, and it is thus possible to stably form the solder balls 23 in the manufacturing process and improve the yield. Further, since the end faces 18a of the copper posts 18 are at a slightly lower position, it is possible to decrease the gap between the first package 1a and the second package 2 relative to the solder balls 23 of the same size, and thereby the stacked type semiconductor device can be reduced in size.

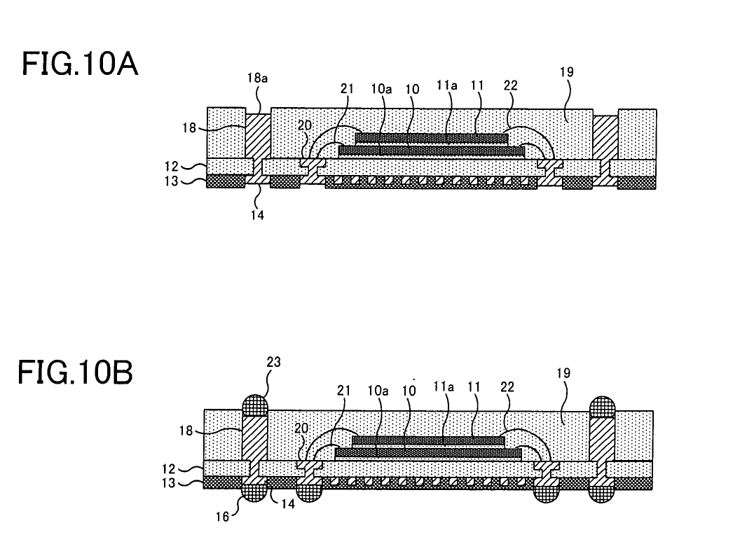

The method of manufacturing the stacked type semiconductor device of FIG. 9 will be described next using FIG. 10. Here, the above-described steps of FIGS. 2 to 7 of the first embodiment are commonly applicable to the second embodiment, so descriptions thereof will be omitted. Meanwhile, the second embodiment differs from the first embodiment in FIG. 10 corresponding to FIG. 8 of the first embodiment, as described below.

First, from the state of FIG. 7B, as shown in FIG. 10A, a laser beam is applied to a region of the resin sealing layer 19 at each position of the copper post 18 to remove the upper portion, and thereby the end faces 18 of the copper posts 18 are exposed. In this case, it is required to adjust heights of the copper posts 18 and the resin sealing layer 19 in the state of FIG. 7B previously so that a desired difference between the heights is obtained. Subsequently, as shown in FIG. 10B, the solder balls 23 are disposed and attached to the end faces 18a of the copper posts 18. Then, the second package 2 assembled beforehand is mounted on the solder balls 23, and thereby the stacked type semiconductor device having the structure as shown in FIG. 9 is completed.

Next, a stacked type semiconductor device which is a modification of the second embodiment will be described. In the modification of the second embodiment described below, as well as the feature of the exposed end faces 18a of the copper posts 18 which are formed at a lower position on the upper portion of the first package 1a as shown in FIG. 9, it is another feature that the surface of the resin sealing layer 19 itself is not flat, but has a step structure. The basic structure except the features is common to that of the above-described second embodiment.

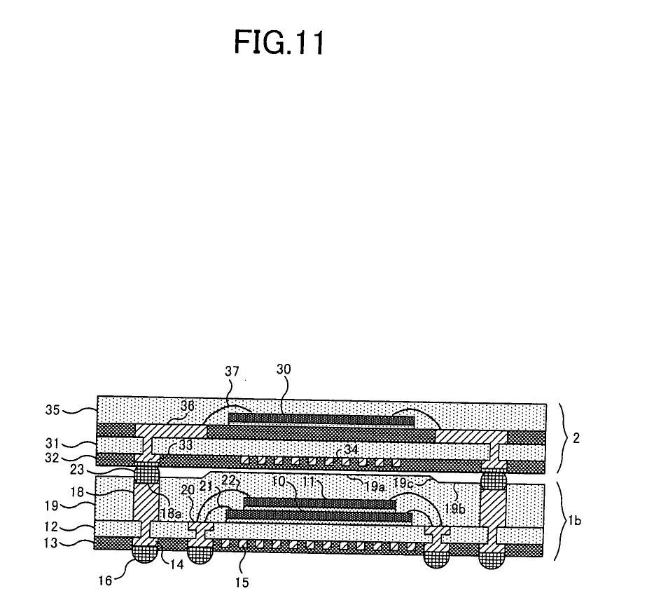

FIG. 11 shows a cross-sectional structure of the stacked type semiconductor device of the modification of the second embodiment. In the modification as shown in FIG. 11, the resin sealing layer 19 of the first package 1b has a convex surface such that the center portion is higher than the peripheral portion on the resin sealing layer 19. In other words, on the surface of the resin sealing layer 19, a step structure is formed such that a central area 19a is higher than a peripheral area 19b by a predetermined height, and a slope portion 19c is formed between the areas 19a and 19b. In addition, the structure of the end faces 18a of the copper posts 18 are the same as the

Herein, the height of the central area 19a is limited by the height of the bonding wire 22 protruding from the surface of the semiconductor chip 11 and the thickness of the resin sealing layer 19 covering the upper portion of the bonding wire 22. Meanwhile, the height of the peripheral area 19b is not limited by such factors and can be adjusted by removing the upper portion of the resin sealing layer 19. Accordingly, by adopting the structure as shown in FIG. 11, it is possible to lower the position of the peripheral area 19b relatively, while securing the height of the central area 19a, and thereby the upper-layer second package 2 can be mounted at a lower position. In addition thereto, the effect of lowering the height of the end faces 18a of the copper posts 18 is also obtained, so that it is further possible to thin the entire stacked type semiconductor device.

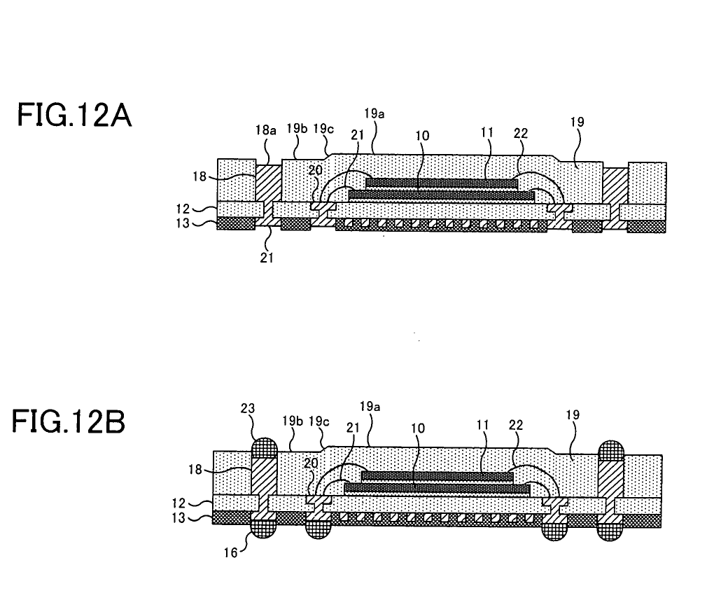

The manufacturing method of the stacked type semiconductor device of FIG. 11 will be described using FIG. 12. Herein, the above-described steps of FIGS. 2 to 7A of the first embodiment are commonly applicable to each step of the modification of the second embodiment, so descriptions thereof will be omitted. Meanwhile, the modification of the second embodiment differs from the first embodiment in steps corresponding to FIGS. 7B and 8, as shown in FIG. 12.

First, from the state of FIG. 7A, as shown in FIG. 12A, the first package 1b is covered and by the resin sealing layer 19, and the surface is treated such that the above-described step structure including the central area 19a, the peripheral area 19b and the slope portion 19c is formed. In this case, by using a resin mold having a convex shape, it is possible to mold the shape of the step structure as shown in FIG. 12A.

Next, as shown in FIG. 12B, the solder balls 23 are disposed and attached to the end faces 18a of the copper posts 18 by the same method as in FIG. 10B. Thereafter, the second package 2 assembled beforehand is mounted on the solder balls 23, and thereby the stacked type semiconductor device having the structure as shown in FIG. 12 is completed.

In the above-described modification of the second embodiment, the case in which the step structure of the surface of the resin sealing layer 19 is formed, as well as the structure of the end faces 18a of the copper posts 18. However, a stacked type semiconductor device having only the step structure of the surface of the resin sealing layer 19 can be realized. That is, by applying the step structure of the resin sealing layer 19 as shown in FIG. 11 in addition to the structure of the stacked type semiconductor device as shown in FIG. 1, it is also possible to lower the height of the first package 1 and the second package 2 as a whole.

Although in the foregoing the present invention is specifically described based on the first and second embodiments, the present invention is not limited to each embodiment described above, and is capable of being carried into practice without departing from the scope of the subject matter thereof. For example, the stacked type semiconductor device of the embodiments has a two-layer structure including the lower-layer first package 1 (1a, 1b) and the upper-layer second package 2, but the present invention is widely applicable to stacked type semiconductor devices having a larger number of stacked type semiconductor packages. In this case, the electrode structure of the first package 1 of the embodiment is formed in each semiconductor package except the highest layer, and a typical package can be stacked on the highest layer. Further, for the electrode structure using the copper posts 18 in the embodiments, the present invention is widely applicable to the case of forming the electrode structure by a conductive post using another conductive material.

In the first and second embodiments, the method of etching the copper plate 50 is adopted to form the copper posts 18 in the manufacturing process of the stacked type semiconductor device, and by using the copper plate 50 in such a manner, it is possible to determine the height of the copper posts 18 with high accuracy. When high accuracy is ensured for the height of the copper posts 18, after sealing the first semiconductor package 1 by the resin sealing layer 19, it is possible to easily expose the electrode portion of the end faces of the copper posts 18, and to improve assembly efficiency in stacking a number of semiconductor packages.

The present invention is not limited to the above described embodiments, and various variations and modifications may be possible without departing from the scope of the present invention.

This application is based on the Japanese Patent application No. 2006-011674 filed on Jan. 19, 2006, entire content of which is expressly incorporated by reference herein.

What is claimed is:

1. A semiconductor package comprising:
a substrate containing a wiring pattern connected to a plurality of external electrodes;
one or more semiconductor chips connected to said wiring pattern and mounted on said substrate;
a conductive post connected to a predetermined said external electrode and functioning as a relay electrode in a vertical direction; and
a resin sealing layer for integrally sealing said semiconductor chips and said conductive post in a state in which an upper end face of said conductive post is exposed.

2. A semiconductor package according to claim 1, wherein said conductive post is made of copper.

3. A semiconductor package according to claim 1, wherein said plurality of external electrodes and a connection electrode to be connected to the upper end face of said conductive post are solder balls.

4. A semiconductor package according to claim 3, wherein the exposed end face of said conductive post is formed at a position lower than a surface of said resin sealing layer.

5. A semiconductor package according to claim 3 or 4, wherein on a surface of said resin sealing layer, a height of a peripheral area including a position of said conductive post is lower than a height of a central area.

6. A substrate with a conductive post comprising:
a substrate containing a wiring pattern connected to a plurality of external electrodes;
one or more lands formed on said conductive post and connected to one or more semiconductor chips; and
a conductive post connected to a predetermined said external electrode and functioning as a relay electrode in a vertical direction.

7. A substrate with a conductive post according to claim 6, wherein said conductive post is made of copper.

8. A stacked type semiconductor device which is formed by stacking a plurality of semiconductor packages including said semiconductor package according to claim 1, and enables connection from said predetermined external electrode to a desired semiconductor package through said conductive post.

9. A stacked type semiconductor device according to claim 8, wherein said plurality of external electrodes and a connection electrode for connecting between adjacent upper and lower semiconductor packages are solder balls.

10. A manufacturing method of a semiconductor package comprising the steps of:
forming a substrate structure having a wiring pattern and a plurality external electrodes on one side of a conductive plate such that a predetermined said external electrode is connected to a position at which said conductive plate partially functions as a relay electrode;
forming a conductive post on the other side of said conductive plate by using a portion at a location functioning as said relay electrode while removing the other portion;
mounting one or more semiconductor chips on a surface of said substrate structure at a side on which said conductive plate is removed;
sealing said one or more semiconductor chips and said conductive post integrally with a resin; and
treating a surface of said resin so that an end face of said conductive post is exposed.

11. A manufacturing method of a semiconductor package according to claim 10, wherein said conductive post is made of copper.

12. A manufacturing method of a semiconductor package according to claim 10, wherein said plurality of external electrodes and a connection electrode to be connected to the upper end face of said conductive post are solder balls.

13. A manufacturing method of a semiconductor package according to claim 12, further comprising a step of exposing an upper end face of said conductive post at a height slightly lower than a height of a surface of said resin by removing the upper end face of said conductive post.

14. A manufacturing method of a semiconductor package according to claim 12 or 13, further comprising a step of forming a peripheral area including a position of said conductive post on a surface of said resin at a height slightly lower than a height of a central area.

15. A manufacturing method of a stacked type semiconductor device including said semiconductor package according to claim 1, wherein a connection electrode is connected to the upper exposed end face of said conductive post for connection to one ore more other semiconductor packages in series so as to provide an electrical connection from said predetermined external electrode to a desired semiconductor package through said conductive post.
